(19) United States
(12) Patent Application Publication
(10) Pub. No.: US 2002/0063568 A1
(43) Pub. Date: May 30, 2002

(54) Multi-device automated test station (MATS)

(76) Inventor: Henry H. Hung, Phoenix, AZ (US)

Correspondence Address: Tod R. Nissle, Esq., TOD R. NISSLE, P.C., P.O. Box 55630, Phoenix, AZ, 85078, US

(21) Appl. No.: 09/726,917

(22) Filed: Nov. 30, 2000

(51) Int. Cl. G01R 31/308

(52) U.S. Cl. 324/753

(57) ABSTRACT

A method and apparatus for testing simultaneously a plurality of optical circuits automatically cycles through and controls a plurality of selected test for each of the optical circuits. The test parameters for one optical circuit can be altered independently of the remaining optical circuits. A test report is prepared for each optical circuit and shipped with the circuit. A thermoelectric cooler is used to vary the temperature of each optical circuit.

This invention relates to an apparatus and method for testing an optical circuit.

More particularly, the invention relates to an apparatus and method for testing simultaneously a plurality of optical circuits.

An integrated optic chip (IOC) is made of an electro-optic material whose index of refraction increases or decreases depending on the direction of electric field applied to it. IOC's are analogous to integrated circuits (IC's) utilized in semiconductor technology. The signal processing in an IC is totally electric whereas in an IOC it is both optical and electrical. The term “integrated” in “integrated optic chip” implies that the chip has both electrical and optical parts. One or more external electrical signal(s) is applied to one or more electrodes formed on an IOC and the electrical signals change the index of refraction of one or more waveguides adjacent to the electrodes. Changing the index of refraction of a waveguide produces a concomitant change in the intensity and/or phase of light passing through the waveguide. An IOC device is a device which includes one or more IOCs.

An optical circuit is a circuit which includes one or more IOCs or which transmits light through a solid material that comprises part of the circuit.

Conventional testing of integrated optic chip (IOC) devices is done one device at a time in a large temperature chamber. Several disadvantages are associated with this conventional testing procedure. First, the large mass of a conventional temperature chamber requires a long time to heat or cool to a selected stable temperature. As a result, it takes an extended period of time to test an IOC device. Second, the capital equipment cost of conventional temperature chambers is large. Third, directing optical fibers into and from the temperature chamber increases the likelihood the fibers will be broken. Fourth, the conventional testing procedure is labor intensive, consumes large amounts of electrical energy, and is not suitable for large scale manufacturing.

Accordingly, it would be highly desirable to provide an improved apparatus and method for testing optical circuits.

Therefore, it is a principal object of the invention to provide an improved apparatus and method for testing IOC devices and other optical circuits.

These and other, further and more specific objects and advantages of the invention will be apparent from the following detailed description thereof, taken in conjunction with the drawing, in which:

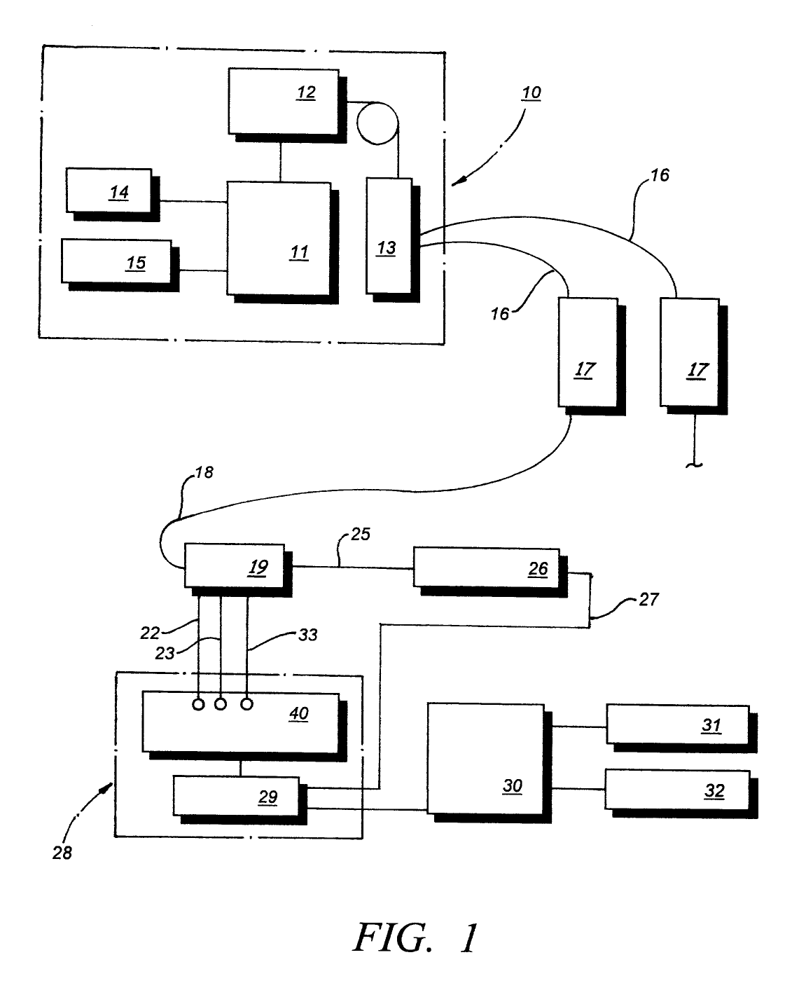

FIG. 1 is a block diagram illustrating a light source and optical circuit test apparatus constructed in accordance with the principles of the invention;

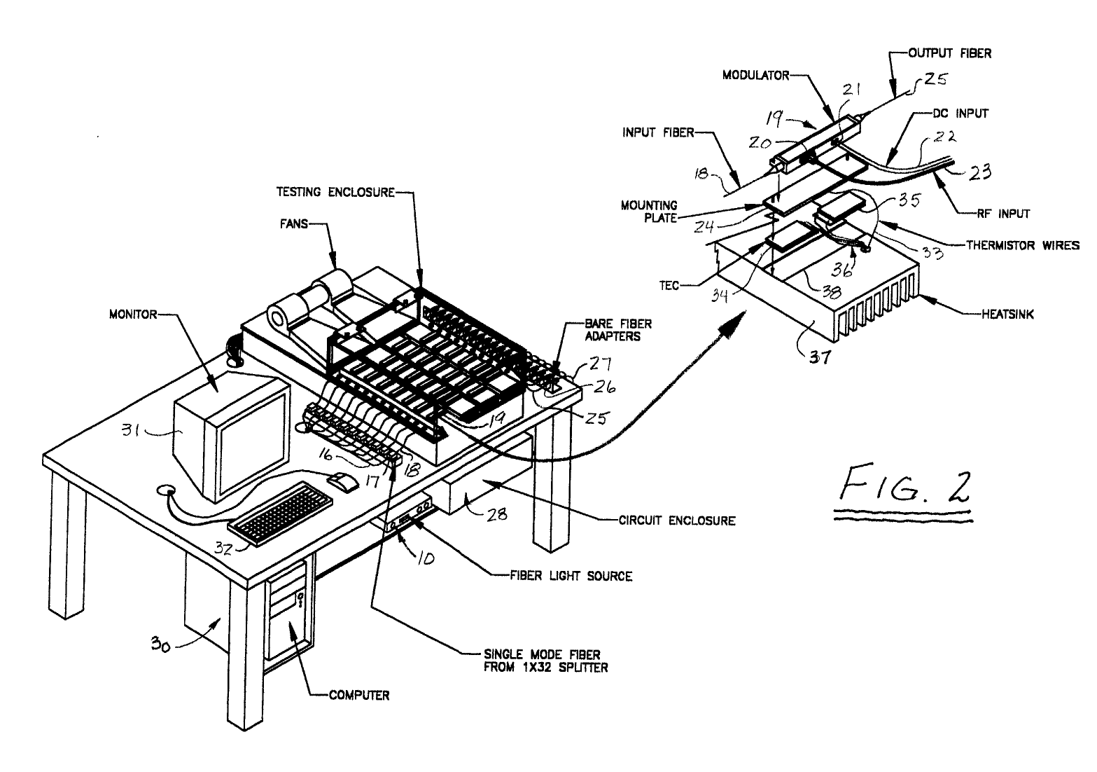

FIG. 2 is perspective view further illustrating the optical circuit test apparatus of FIG. 1; and,

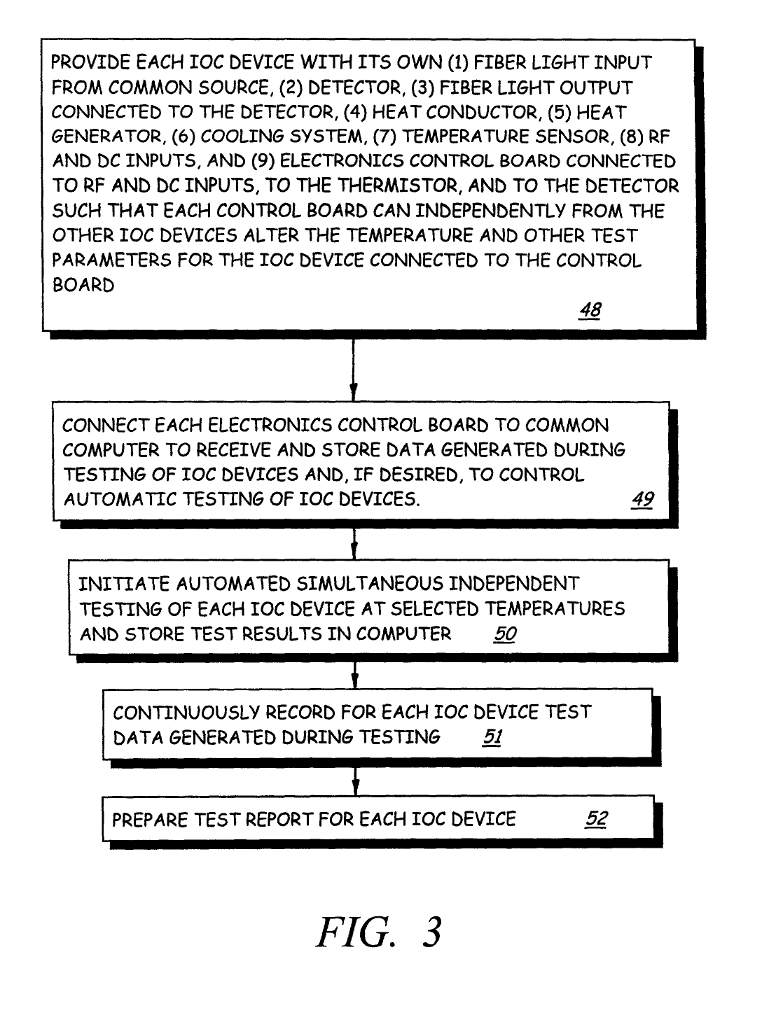

FIG. 3 is a block flow diagram illustrating a testing procedure in accordance with the invention.

Briefly, in accordance with the invention, I provide an improved method for testing a plurality of optical circuits. The method comprises the steps of applying test signals to each of the circuits; and, receiving test data from each of the optical circuits at a common data collection center.

In another embodiment of the invention, I provide an improved method for testing a plurality of optical circuits. The method includes the steps of programming circuitry to automatically cycle through and control selected tests for each of the optical circuits, and using the circuitry to automatically cycle through and control the selected tests for each of the optical circuits.

In a further embodiment of the invention, I prove an improve method for testing a plurality of optical circuits. The method includes the steps of programming circuitry to conduct and control selected tests for each of the optical circuits within selected test parameters; and altering the test parameters for at least one of the optical circuits independently from the test parameters for the remaining ones of the optical circuits.

In still another embodiment of the invention, I provide an improved method for testing an optical circuit. The method includes the steps of testing at least one selected property of the optical circuit at at least two different selected temperatures to generate test data; and, continuously recording the test data while the optical circuit is tested at the selected temperatures.

In yet a further embodiment of the invention, I provide an improved method for testing an optical circuit. The method includes the steps of monitoring the DC bias stability of the circuit during a selected period of time.

In yet still another embodiment of the invention, I provide an improved method for testing an optical circuit. The improved method includes the steps of testing a plurality of selected properties of the optical circuit; preparing a report of the results of the testing; and, including the report with the optical circuit when the optical circuit is shipped to a selected destination.

In a further embodiment of the invention, I provide an improved method for testing a plurality of optical circuits, including the step of simultaneously individually testing said circuits.

In another embodiment of the invention, I provide an improved method for testing an optical circuit, including the step of using a thermoelectric cooler to vary the temperature of the optical circuit.

In still a further embodiment of the invention, I provide an improved method for testing a plurality of optical circuits, including the step of using a single light source to provide the light to test each of the circuits.

Turning now to the drawings, which depicts the presently preferred embodiment of the invention for the purpose of illustrating the practice thereof, and not by way of limitation, in FIG. 1 a source 10 of broadband light includes COMM 14, power 15, bias board 11, laser diode 12, and coupler/splitter 13. Laser diode 12 and coupler 13 are interconnected by a loop of erbium-doped fiber. Light from laser diode 12 excites erbium electrons in the fiber loop to a new energy level or orbit. When the electrons decay back to their original energy level or orbit, they emit secondary light. The secondary light is broadband light having a wavelength in the range of 1530 nm to 1560 nm. The secondary light travels from the erbium fiber 12A to isolator—splitter unit 13. Unit 13 includes an isolator which protects laser diode 12 from reflections that travel back through fiber 12A toward diode 12. Unit 13 also functions to split the secondary light into a plurality of auxiliary beams each having an equivalent mix of wavelengths in the range of 1530 nm to 1560 nm. Each auxiliary beam is directed from unit 13 down a separate single mode (SM) fiber 16 to a separate polarizer 17, and is directed from polarizer 17 through a polarization maintaining (PM) fiber 18 into a separate IOC device 19. I.e., each auxiliary beams from unit 13 is directed to a separate, different IOC device.

Output from IOC device 19 travels through single mode fiber 25, into “bullet” bare fiber adapter 26, and into multimode fiber 27. Fiber 27 travels to circuit board enclosure 28, into and through a RS 232 connector, and to a circuit board 29. Board 29 is connected to a computer 30. Computer 30 is used to set controls on board 29 or to otherwise provide board 29 with commands to control the application of direct current to device 19 via circuitry 40 to cable 22 and to control via circuitry 40 the application of RF signals to device 19 via cable 23. Lead 33 is connected to a thermistor in a plate that is beneath and contacting IOC device 19.

Each IOC device has its own separate board 29 which receives output from and controls the testing of the IOC device. The test results for each IOC device are directed by its associated board 29 to computer 30 for storage and analysis.

The RF cable is connected to device 19 with an SMA (sub miniature adaptor). The SMA is similar to a connector for coaxial cable. The female connector is on device 19. The male connector is on the end of cable 23, along with the SMA sleeve which threads over the female connector after the male connector is inserted in the female connector.

Device 19 also includes a connector which enables cable 22 to be attached to the connector and device 19.

The circuit board 29 analyzes the input from fiber 27 and sends the results of the analysis to computer 30 for storage.

FIG. 2 further illustrates test apparatus constructed in accordance with the principles of the invention. In FIG. 2, each fiber 16 leads to a different polarizer 17, and each fiber 18 lead from a different polarizer 17 to a different IOC device 19. Further, each fiber 25 leads to a different adapter or coupler 26, and each fiber 27 leads from a different adapter 26 to a different circuit board 29 in circuit enclosure 28. Each device 19 has its own associated DC cable 22, RF cable 23, and themistor 33 connected to circuitry 40 in circuit enclosure 28.

Each IOC device 19 sets on and contacts an aluminum heat conductive mounting plate 24. Plate 24 is bonded to thermo-electric coolers (TECs) 34, 35 with a heat conductive epoxy material. The epoxy or other oadhesive must be elastic at low temperatures to compensate for and adapt to the expansion and contraction of plate 24 with change in temperature. Ohterwise, there is a risk that contraction or expansion of plate 24 will crack the TECs. If desired, instead of a heat conductive epoxy or other adhesive, an insulated mechanical clamp can be utilized to secure TECs to plate 24. A plate or member made from brass, gold, copper, or another electrically conductive material(s) can be utilized in place of or in conjunction with aluminum plate 24.

A thermoelectric cooler (TEC) is a solid-state heat pump. A TEC provides temperature stabilization and cycling or cooling and heating below and above ambient temperature during testing of IOC devices. A typical TEC uses a pair of thin ceramic wafers with a series of P-doped and N-doped bismuth-telluride semiconductor materials sandwiched between the ceramic wafers. The N-type material has an excess of electrons while the P-type material has a deficit of electrons. When electrons move from the P-type material to the N-type material, the electrons absorb energy in the form of heat, creating a cold junction. When electrons move from the N-type material to the P-type material, the electrons give off energy, creating a hot junction. The direction of current flow in the TEC determines whether electrons flow from the P-type material to the N-type material, or vice-versa. Current is directed through TECs 34, 35 via wires 36.

Each TEC is in contact with a heat sink 37 which dissipates heat from the TEC. Water, air, or another desired material is used to carry heat away from heat sink 37. Chilled water or air is presently preferred and is caused to flow over and contact sink 37 to absorb and carry heat away from sink 37. Groups of eight to ten TECs are presently mounted on each heat sink, even though in FIG. 2 only a single TEC is shown mounted in a groove 38 formed on the top of heat sink 37.

As noted, each IOC device 19 has its own separate aluminum plate 24. Each plate 24 has its own associated TEC(s). Each plate 24 is also connected to its own separate thermistor by wires 33 to enable the temperature of plate 24 to be monitored separately from the remaining plates 24 each associated with one of the other IOC devices 19 being tested. A thermistor is a temperature sensitive resistor and is typically a semiconductor who resistance is a known function of the temperature.

The TEC(s) associated with a plate 24 enables the temperature of the plate 24 to be controlled to an accuracy of about 0.1 degrees C. The TECs 34, 35 in FIG. 2 can be used to cause the IOC device 19 on plate 24 to reach its programmed temperature within about five minutes.

The RF cable 23 is connected to the female connector 20 on device 19 with an SMA (sub miniature adaptor).

The DC cable 22 is connected to connector 21 on device 19.

In operation of the apparatus illustrated in FIGS. 1 and 2, the light source 10 is operated. Light source 10 can utilize the erbium fibers described above to generate broadband light, can utilize a semiconductor laser to generate broadband light by killing reflections from both sides of the facets, or can utilize any other means to produce broadband light. Light source 10 produces a plurality of auxiliary broadband light beams. Each auxiliary beam has an equivalent mix of wavelengths in the range of 1530 nm to 1560 nm, is directed from unit 13 down a separate single mode (SM) fiber 16 to a separate polarizer 17, and is directed from polarizer 17 through a polarization maintaining (PM) fiber 18 into a separate IOC device 19. I.e., each auxiliary beam from unit 13 is directed to a separate IOC device 19.

Computer 30 is utilized to control each circuit board 29. Each circuit board 29 controls and monitors a separate IOC device 19. Each circuit board 29 causes appropriate current to flow through wires 36 and monitors the temperature of a plate 24 to insure that the temperature of the IOC device 19 contacting plate 24 reaches the desired temperature. Circuit board 29 then directs selected RF signals through cable 23 or selected DC signals through cable 22. The polarity or magnitude of current to the TECs adjacent a plate 24 is utilized to adjust the temperature of the plate 24.

Output from IOC device 19 travels through single mode fiber 25, into “bullet” bare fiber adapter 26, and into multimode fiber 27. Fiber 27 travels to board 28 and into and through a RS 232 connector and to a circuit board 29. Board 29 includes a detector. Board 29 is connected to a computer 30. Each board 29 monitors the output from its detector for each selected temperature reached by device 19 and for each signal administered to device 19 via cable 22 or 23 when device 19 is heated or cooled to a selected temperature. Computer 30 monitors each board 29. Since a plurality of devices 19 are tested simultaneously, computer 30 is simultaneously monitoring and receiving data from a plurality of boards 29. Computer 30 retains this data in memory, and, when appropriate, analyzes the data to determine if it should send new settings to the board 29 for each device 19 or should direct the board 29 for a device to perform additional tests on the device 19 associated with the board 29. Computer 30 is connected to monitor 31 and keyboard 32.

A testing method in accordance with the invention is set forth in FIG. 3. In step 48, each IOC device is provided with its own (1) fiber light input from common source, (2) detector, (3) fiber light output connected to the detector, (4) heat conductor, (5) heat generator, (6) heating/cooling system, (7) temperature sensor, (8) RF and DC inputs, and (9) electronics control board 29 connected to RF and DC inputs, to the thermistor, and to the detector such that each control board can independently from the other IOC devices alter the temperature and other test parameters for the IOC device connected to the control board.

In step 49, each electronics control board 29 is connected to a common computer to receive and store data generated during testing of IOC devices and, if desired, to control automatic testing of IOC devices.

In step 50, the automated simultaneous independent testing of each IOC device at selected temperatures is initiated, and the test results from each IOC device are simultaneously received by and stored in the memory of common computer 30.

In step 51, the test data generated during testing for each IOC device is continuously recorded in the memory of common computer 30.

In step 52, a test report is generated for each IOC device. The test report can comprise data on a memory disc, can comprise a report printed on paper, or can take any other desired form. The report for each IOC device is shipped with the device to the customer or to another desired destination.

By way of example, and not limitation, the following sets forth a testing procedure for an IOC device which functions as a modulator.

The following standard properties of each IOC device 19 are tested in the manner subsequently described in more detail:

1. RF ON/OFF ratio.

2. RF Vπ.

3. Quadrature control.

a. Over time.

b. Over temperature.

C. At elevated temperature.

4. Power level.

a. Over time.

b. Over temperature.

C. Cut back to measure the insertion loss of the device.

5. Frequency response.

6. Eye diagram.

Mount each of a plurality of IOC devices 19 on its own panel or plate 24. Place by hand each IOC device 19 on a plate 24. Use clamps to secure the IOC device to its plate 24. It is preferred, though not necessary, that the lowest device number be mounted first, followed by the next highest device number, followed by the next highest device number, etc. The same placement scheme is preferably utilized each time for consistency.

For each IOC device 19:

1. Connect input fiber 18 to the input side of IOC device 19.

2. Connect output fiber 25 to the output side of IOC device 19.

3. Connect the RF cable 22 to the female connector 20 of IOC device 19.

4. Connect the DC cable 23 to the connector 21 of IOC device 19. Connector 21 can comprise a pair of DC bias pins.

Utilize keyboard 32 or any other desired data input device to input into computer the device number of the IOC device mounted on the panel 24 in each slot location. Each slot location identifies a particular panel 24 and the TECs, cables 22 and 23, thermistor wires 33, TEC wires 36, etc. associated with that particular panel 24.

Turn on light source 10 to provide broadband light to each IOC device through the input fiber 18 associated with that IOC device.

Use keyboard 32 to direct computer 31 to run the initial test. The initial test performs a test at room temperature of each of the standard properties listed above. Room temperature can vary as desired, but ordinarily is a temperature selected from the range of 65 to 85 degrees Fahrenheit. Bias control begins from this point to servo the DC bias to maintain quadrature operation of the modulator. Bias control consists of actively nulling the second harmonic by monitoring output from the device 19 being tested and by adjusting the voltage applied to device 19 in order to null the second harmonic.

After the initial test, the computer monitor 31 displays the device number of each non-working IOC device 19. A □non-working device□ indicates that there is a problem with either the modulator or the connections to the modulator. Check the connections to each non-working device. If the connections are acceptable and the device is still displayed as non-working, remove the device and replace, if possible, with another device 19. Repeat the initial test to determine if the new device is functional.

Use the keyboard 32 to start the first phase of the primary testing cycle. Once keyboard 32 starts the first phase of the primary testing cycle, each circuit board 29 automatically checks three times during a fifteen minute period the On/Off ratio, Vπ, and loss for its associated device 19. If a tested value for a particular device 19 is out of an appropriate range, the program will request replacement or retesting of the device. The appropriate ranges of tested values normally are similar to industry standards, but can be defined as desired. If a device is replaced, the first phase testing is repeated.

Once each tested value for each device 19 is in its appropriate range, circuit board 29 automatically begins the second phase of the primary testing cycle. During the second phase, circuit board 29 associated with each device 19 tests at room temperature the On/Off ratio, Vπ, DC bias drift, and power level. Each board 29 automatically performs and controls these tests.

1. To test the On/Off ratio, an eight volt p-p (peak to peak) sine wave is applied to the RF connector 20 on a device 19. The maximum and minimum values are recorded. The maximum value is divided by the minimum value and converted to dB by taking 10 log of the quotient. By way of example, and not limitation, the On/Off ratio is presently at least 13 dB, with at least 20 dB being preferred.

2. To test Vπ, the amplitude of the sine wave applied to the RF connector 20 is adjusted to minimize the 1^{st} harmonic. The second harmonic is not minimized. The value of the sine wave is then divided by 1.2 to obtain the RF Vπ. By way of example, and not limitation, the RF Vπ presently should be about six volts.

3. To test DC bias drift, the bias control function is turned on so that the modulator is maintained at quadrature. The quadrature point is at π/2.

This is the most linear part of the sine wave where there is the least amount of distortion. If DC bias drift occurs, at the quadrature point the drift of and presence of 2^{nd} harmonics in the sine wave to the left or right is evident. The voltage applied to the device 19 at connector 21 is adjusted to move the sine wave right or left back to its desired location. DC bias drift is determined by keeping track of such voltage adjustments. The temperature for the modulator is set to room temperature during the testing of DC bias drift. The bias voltage drift is recorded over time. By way of example, and not limitation, it is presently desired that the DC bias drift be between −6 volts and +6 volts.

4. To test power level, the bias control function is turned on so that the modulator is maintained at quadrature. The temperature for the modulator is set at room temperature. The power level drift is recorded over time.

Once the second phase of the primary testing cycle is completed, each circuit board 29 automatically begins the third phase of the primary testing cycle. During the third phase, the DC bias drift, power level, Vπ, and On/Off ratio of a device 19 are determined at each of a plurality of temperatures while the temperature of the device 19 is cycled from −10 degrees Celsius to 70 degrees Celsius. Circuit board 29 controls the current flow to the TECs to heat or cool device 19 to a desired temperature. Measurements to determine DC bias drift, power level, Vπ, and On/Off ratio are presently made at temperature increments of five degrees. The size of the temperature increments can vary as desired. Once a desired temperature is reached, one minute is allowed to pass so the temperature of device 19 stabilizes. Then measurements are taken every ten seconds during the subsequent minute, after which the temperature of the device 19 is raised (or lowered) another five degrees. It presently takes about three minutes to increase (or decrease) the temperature of a device 19 by five degrees.

1. To test DC bias drift, the bias control function is turned on so the device 19 is maintained at quadrature. The temperature of the device 19 is cycled through five degree increments in the manner described above from −10 degrees Celsius to 70 degrees Celsius. After the temperature of the device stabilizes for one minute at each selected temperature (for example, at −10 degrees, −5 degrees, 0 degrees, 5 degrees, 10 degrees, 15 degrees, etc.) measurements are taken at ten second intervals during the subsequent minute at each selected temperature. The bias voltage drift measurements are recorded in the memory of computer 30.

2. To test power level, the bias control function is turned on so the device (modulator) 19 is maintained at quadrature. The temperature of the device 19 is cycled through five degree increments in the manner described above from −10 degrees Celsius to 70 degrees Celsius. Measurements are taken for a minute at ten second intervals while the temperature of device 19 has stabilized at each selected temperature. The power level drift measurements are recorded in the memory of computer 30.

Measurements of the On/Off ratio and Vπ are made in the manner earlier described.

After the third phase of the primary testing cycle is completed, the operator performs a frequency response test by connect device 19 to an HP 8703 and by placing a hold on the bias. The HP 8703 is a network analyzer that measure the RF characteristics of device 19. When a hold is placed on the bias, the value of the bias is frozen or fixed and is not allowed to change. This is done using the control panel which appears on the screen of monitor 31 and is associated with the software used in conjunction with the test. Data comprising all measurements and tests made on each device during all three phases of the primary testing cycle for each device 19 is stored in the memory of computer 30 to be included in a report prepared for each device 19 to set forth the results of the test.

If a frequency response test is not performed, an Eye Diagram Test is run in its place while the device 19 is held at quadrature. A pattern generator is connected to the RF input 20 of the device and a digitizing scope is attached to output fiber 25. The pattern generator produces a 10 Gbs random pattern that will create an Eye Diagram. The resulting Eye Diagram is viewed on the digitizing scope and indicates how far the 2^{nd} harmonic is suppressed when the modulator (device 19) is biased and a signal is applied to the modulator.

A CSO test is performed on device 19 using an external signal generator and a spectrum analyzer. During the test the bias is fixed or frozen.

When device 19 is at room temperature, a cutback is performed by cutting the input fiber 18 attached to the device 19. The cut end, which is receiving light from source 10, is put in a power meter to determine the intensity of light emanating from fiber 18. The intensity of light coming out of the cut end of the fiber 18 is compared to the intensity of light which was entering the output fiber 25 (and was detected by the detector on circuit board 29). The cutback is performed at quadrature or at maximum output light power. The maximum output light power is the maximum output from the device 19 being tested. By way of example, and not limitation, the loss of light intensity as light passes through device 19 is presently preferably 5.5 dB or less.

Data from the CSO, frequency response test, and/or eye diagram is saved in the memory of computer 30 to be included in a report prepared for each device 19 to set forth the test reults for the device 19.

Having described my invention in such terms as to enable those of skill in the art to understand and practice it, and having described the presently preferred embodiments thereof, I claim:

1. A method for testing a plurality of optical circuits comprising the steps of
(a) applying test signals to each of said circuits; and,
(b) receiving test data from each of said optical circuits at a common data collection means.

2. A method for testing a plurality of optical circuits comprising the steps of
(a) programming circuitry to automatically cycle through and control selected tests for each of said optical circuits, and
(b) using said circuitry to automatically cycle through and control said selected tests for each of said optical circuits.

3. A method for testing a plurality of optical circuits, including the steps of
(a) programming circuitry to conduct and control selected tests for each of said optical circuits within selected test parameters; and
(b) altering the test parameters for at least one of said optical circuits independently from the test parameters for the remaining ones of said optical circuits.

4. A method for testing an optical circuit, including the steps of
(a) testing at least one selected property of the optical circuit at at least two different selected temperatures to generate test data; and,
(b) continuously recording said test data while said optical circuit is tested at said selected temperatures.

5. A method for testing an optical circuit, including the steps of monitoring the DC bias stability of said circuit during a selected period of time.

6. A method for testing an optical circuit, including the steps of
(a) testing a plurality of selected properties of the optical circuit;
(b) preparing a report of the results of said testing; and,
(c) including said report with said optical circuit when said optical circuit is shipped to a selected destination.

7. A method for testing a plurality of optical circuits, including the step of simultaneously individually testing said circuits.

8. A method for testing an optical circuit, including the step of using a thermoelectric cooler to vary the temperature of the optical circuit.

9. A method for testing a plurality of optical circuits, including the step of using a single light source to provide the light to test each of said circuits.
